(19) United States
(12) Patent Application Publication
(10) Pub. No.: US 2013/0342669 A1
(43) Pub. Date: Dec. 26, 2013

(54) METHOD FOR AUTO-ADJUSTING AUDIO OUTPUT VOLUME AND ELECTRONIC APPARATUS USING THE SAME

(71) Applicant: WISTRON CORP., New Taipei City (TW)

(72) Inventor: Ching-Hua HSU, NEW TAIPEI CITY (TW)

(73) Assignee: WISTRON CORP., NEW TAIPEI CITY (TW)

(21) Appl. No.: 13/681,423

(22) Filed: Nov. 20, 2012

(30) Foreign Application Priority Data
Jun. 22, 2012 (TW) 101122428

(51) Int. Cl. H04N 7/00; H03G 3/20

(52) U.S. Cl. CPC H04N 7/002; H03G 3/20
USPC 348/77

(57) ABSTRACT

A method for auto-adjusting audio output volume is disclosed. The method can automatically adjust an output volume according to a distance between a user and a screen. The method may also balance a left and right audio channel according to an angle between the user and the screen to provide a better display quality. An electronic apparatus using the method is also disclosed.

### RELATED APPLICATIONS

This application claims priority to Taiwan Application Serial Number 101122428, filed Jun. 22, 2012, which is herein incorporated by reference.

### BACKGROUND

1. Field of Invention

The present invention relates to an audio output volume method and an electronic apparatus using the same. More particularly, the present invention relates to a method and an electronic apparatus for auto-adjusting audio output volume.

2. Description of Related Art

Along with the development of 3C (Computer, Communications and Consumer-Electronics) industries, more and more people are using mobile devices as a tool to provide assistance in their daily lives. Common mobile devices include personal digital assistants (PDAs), mobile phones, smart phones and so on. These mobile devices are small in size and easy to carry, and as a result, the number of people using mobile devices is increasing. With such increased use, the number of functions required on mobile devices is also increasing. The ability to play audio and video content is a basic requirement in a mobile device. In order to display music, play audio data, or use a video telephone, a speaker is necessary.

One or more speakers are typically disposed on or embedded within a surface of an electronic apparatus that faces the user, for example, near a screen of the electronic apparatus, so as to output sound to the user. However, such an electronic apparatus is placed at a predetermined position for use in watching a movie or video. The sound quality received by the user may be affected when the user changes position.

### SUMMARY

The present disclosure provides a method for auto-adjusting output volume. The method adjusts the output volume and/or balances left and right audio channels according to the position of a user.

An embodiment of an aspect of the invention provides a method for auto-adjusting audio output volume. The method includes capturing an image, recognizing a human face area in the image, comparing a height of the human face area to a height of the image for obtaining a ratio, and adjusting an output volume according to the ratio.

Another embodiment of the aspect of the invention provides a method for auto-adjusting audio output volume. The method includes capturing an image, recognizing a human face area of the image, comparing a border of the human face area to a border of the image for obtaining a relative offset value, and adjusting a right audio channel output volume or a left audio channel output volume according to the relative offset value.

An embodiment of another aspect of the invention provides an electronic apparatus for auto-adjusting audio output volume, which includes an image sensor for capturing an image, an image processor for recognizing a human face area in the image and comparing a height of the human face area to a height of the image for obtaining a volume adjusting value, an audio processing unit for receiving the volume adjusting value and an audio source data, and a speaker. The audio processing unit further transforms the audio source data to a sound data, in which an output volume of the sound data is adjusted according to the volume adjusting value. The speaker outputs the sound data provided by the audio processing unit.

Another embodiment of the aspect of the invention provides an electronic apparatus for auto-adjusting audio output volume, which includes an image sensor for capturing an image, an image processor for recognizing a human face area in the image and comparing a border of the human face area to a border of the image for obtaining a volume compensation value, an audio processing unit for receiving the volume compensation value and an audio source data, and a speaker. The audio processing unit transforms the audio source data to a sound data, in which the audio processing unit comprises a left audio channel register and a right audio channel register, and the volume compensation value is sent to the left audio channel register or the right audio channel register. The speaker outputs the sound data provided by the audio processing unit. The speaker comprises a left audio channel and a right audio channel. An output volume of the left audio channel is controlled by the left audio channel register, and an output volume of the right audio channel is controlled by the right audio channel register.

The present disclosure can automatically adjust the output volume and/or balance the left and right audio channels by detecting the distance and/or the angle between a user and the screen to provide a better sound quality.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow chart of a first embodiment of a method auto-adjusting audio output volume of the invention;

FIG. 2 is a flow chart of a second embodiment of the method for auto-adjusting audio output volume of the invention;

FIG. 3 is a flow chart of a third embodiment of the method for auto-adjusting audio output volume of the invention;

FIG. 4 is a flow chart of a fourth embodiment of the method for auto-adjusting audio output volume of the invention;

FIG. 5 is a schematic diagram of an embodiment of an electronic apparatus for auto-adjusting audio output volume of the invention; and

FIG. 6 is a block diagram of the electronic apparatus shown in FIG. 5.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

The present disclosure provides a method for auto-adjusting audio output volume to automatically adjust an audio output volume of an electronic apparatus. The method involves detecting a relative position between a user and a screen (e.g., a distance between the user and the screen and/or an angle between the user and the screen) to adjust the output volume and/or balance left and right audio channel output volume, thereby improving sound quality.

The method for auto-adjusting audio output volume can be utilized in an electronic apparatus that is able to play audio and video content, such as a smart phone, a tablet computer, a laptop computer, or a home theater.

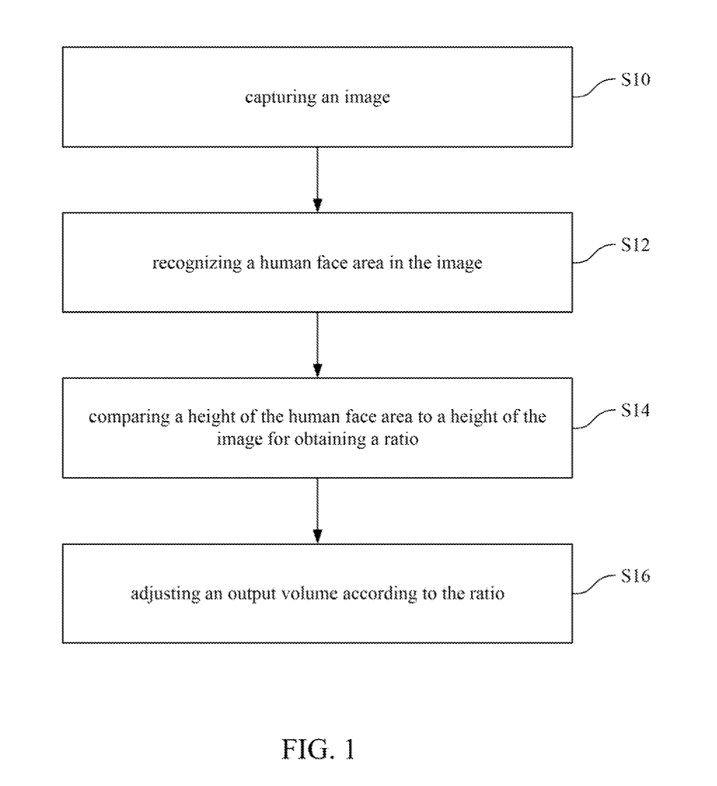

FIG. 1 is a flow chart of a first embodiment of a method for auto-adjusting audio output volume of the invention. In this embodiment, the output volume is adjusted according to a distance between a user and an electronic apparatus. In Step S10, an image is captured. The image is captured by an image sensor of the electronic apparatus. The image sensor can be a charge-coupled device (CCD) image sensor or a complementary metal-oxide-semiconductor (CMOS) image sensor.

In step S12, a human face area is recognized in the image. More particularly, the electronic apparatus includes an image processor. The image captured by the image sensor is sent to the image processor, and a facial recognition technique is utilized or recognizing the human face area in the image.

In step S14, a height of the human face area is compared to a height of the image for obtaining a ratio. More particularly, after the human face area is recognized by the image processor, a pixel number of the height of the human face area is compared to a pixel number of a height of a screen of the electronic apparatus (e.g., the full screen of the image) for obtaining the ratio.

In step S16, an output volume is adjusted according to the ratio. More particularly, there is a predetermined chart built in the image processor, and the ratio is compared to the predetermined chart to thereby obtain a volume adjusting value. The volume adjusting value is sent to an audio processing unit of the electronic apparatus. The audio processing unit receives an audio source data and transforms the audio source data to a sound data, and the sound data is sent to a speaker for output. The output volume of the speaker is adjusted according to the volume adjusting value received by the audio processing unit.

Namely, when the user gets close to the screen of the electronic apparatus, the ratio of the human face area in the image captured by the image sensor is increased, so that the corresponding volume adjusting value becomes small or a negative value, and consequently, the output volume of the speaker is small. On the other hand, when the user is far from the screen, the ratio of the human face area in the image captured by the image sensor is reduced, so that the corresponding volume adjusting value becomes large, and consequently, the output volume of the speaker is large.

The volume adjusting value can be obtained from the following formula:

(1−ratio)*Maximum volume adjusting value=volume adjusting value,

where the ratio is the ratio of the human face area to the full image as described above.

For example, if it is assumed that the maximum volume adjusting value is 3 dB and that the ratio of the human face area to the full image is 0.25, the corresponding volume adjusting value is 2.25, i.e., the output volume of a left audio channel and a right audio channel is each increased by 2.25 dB. As another example, assuming the same maximum volume adjusting value and that the ratio of the human face area to the full image is 0.5, the corresponding volume adjusting value is 1.5, i.e., the output volume of a left audio channel and a right audio channel is each increased by 1.5 dB. To provide another example, again assuming the same maximum volume adjusting value and that the ratio of the human face area to the full image is 1, the corresponding volume adjusting value is 0, i.e., the output volume of a left audio channel and a right audio channel is not changed. If the user is very close to the screen, the image processor calculates the human face area by a distance between the eyes. In this case, when the ratio of the human face area to the full image is greater than one, the corresponding volume adjusting value becomes a negative value, i.e., the output volume of a left audio channel and a right audio channel is each decreased.

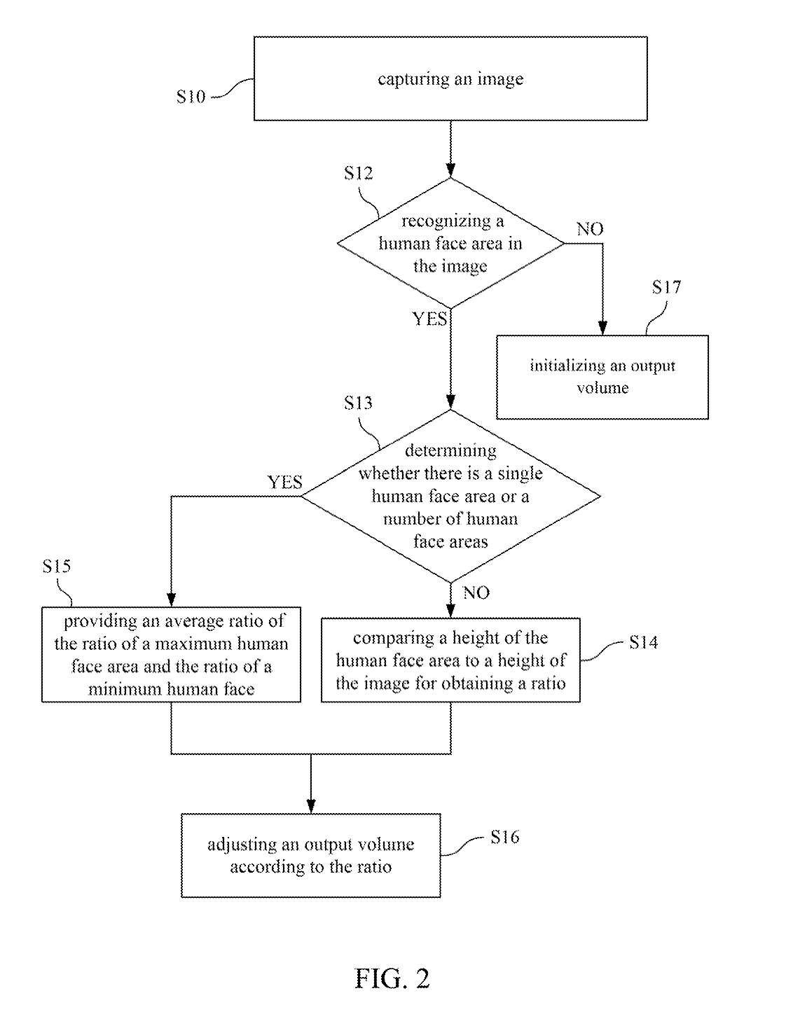

FIG. 2 is a flow chart of a second embodiment of the method for auto-adjusting audio output volume of the invention. The difference between this embodiment and the previous embodiment is that if the human face area cannot be recognized in step S12, for example, the user leaves the area in front of the screen so that there is no longer a human face area in the image, the method goes to step S17. In step S17, the output volume of the speaker is initialized, that is, the output volume of the speaker returns to an initial level.

This embodiment further includes step S13. In step S13, determination is made as to whether there is a single human face area or a number of human face areas. If multiple human face areas are recognized in the image, the method goes to step S15. In step S15, an average ratio of the ratio of a maximum human face area and the ratio of a minimum human face is used in the formula for obtaining the volume adjusting value according to the average ratio to adjust the output volume.

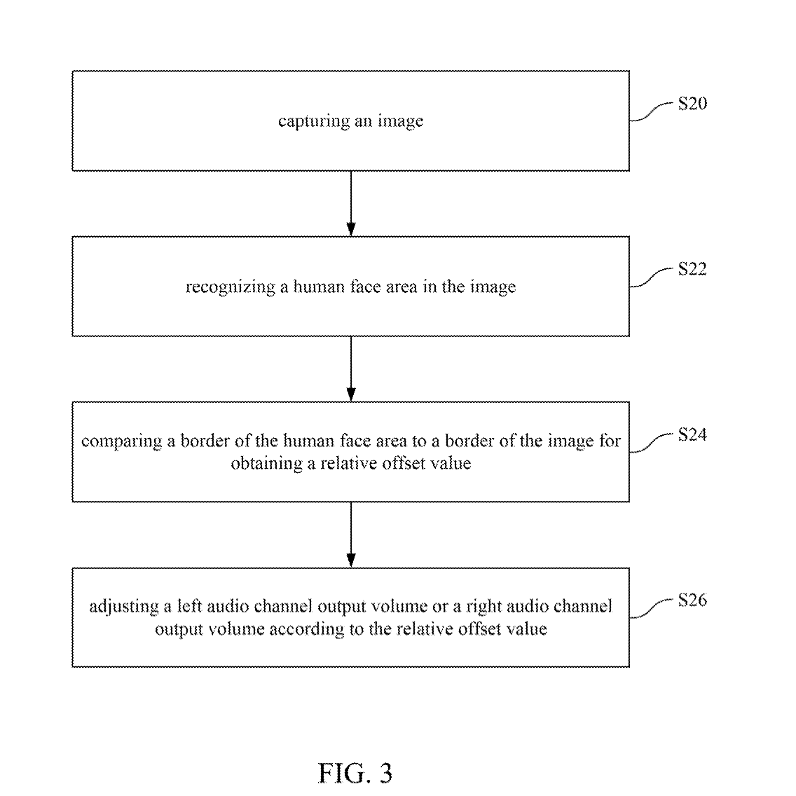

FIG. 3 is a flow chart of a third embodiment of the method for auto-adjusting audio output volume of the invention. In this embodiment, the output volume is adjusted according to an angle between the user and the electronic apparatus for automatically balancing a left audio channel and a right audio channel. In step S20, an image is captured. The image is captured by an image sensor of the electronic apparatus. The image sensor can be a charge-coupled device (CCD) image sensor or a complementary metal-oxide-semiconductor (CMOS) image sensor.

In step S22, a human face area is recognized in the image. More particularly, the electronic apparatus includes an image processor. The image captured by the image sensor is sent to the image processor, and a facial recognition technique is utilized for recognizing the human face area in the image.

In step S24, a border of the human face area is compared to a border of the image for obtaining a relative offset value to compensate the output volume of the left audio channel or the right audio channel. For example, when a compensation of the left audio channel output volume is performed, a left border of the human face area compared to a left border of the full image for obtaining a relative offset value to adjust the left audio channel output volume. When a compensation of the right audio channel output volume is performed, a right border of the human face area is compared to a right border of the full image for obtaining a relative offset value to adjust the right audio channel output volume.

In step S26, the left audio channel output volume or the right audio channel output volume is adjusted according to the relative offset value. A volume compensation of the left audio channel or the right audio channel is obtained from the following equation:

(O/W)*M,

where O is the relative offset value, W is a width of the image, and M is a maximum compensation.

For example, if it is assumed that the maximum volume compensation is 3 dB and that the left border of the human face area aligns to the left border of the image, the relative offset value is 0, the volume compensation is 0, and the left audio channel output volume remains the same. As another example, assuming the same maximum volume compensation and that the left border of the human face area aligns to a middle line of the image, the relative offset value is half of the width of the image, the volume compensation is 1.5 dB, and the left audio channel output volume is increased by 1.5 dB. To provide another example, again assuming the same maximum volume adjust value and that the left border of the human face area aligns to the right border of the image, the relative offset value is the width of the image, the volume compensation is 3 dB, and the left audio channel output volume is increased by 3 dB.

On the other hand, assuming the same maximum volume compensation, if the right border of the human face area aligns to the right border of the image, the relative offset value is 0, the volume compensation is 0, and the right audio channel output volume remains the same. Moreover, with the same maximum volume compensation, if the right border of the human face area aligns to a middle line of the image, the relative offset value is half of the width of the image, the volume compensation is 1.5 dB, and the right audio channel output volume is increased by 1.5 dB. Finally, again with the same maximum volume compensation, if the right border of the human face area aligns to the left border of the image, the relative offset value is the width of the image, and the volume compensation is 3 dB, the right audio channel output volume is increased by 3 dB.

It is noted that the volume compensation can be performed with respect to only the left audio channel or the right audio channel. The volume compensation can be performed multiple times when the user moves relative to the screen. The left audio channel output volume and the right audio channel output volume can be automatically adjusted by the volume compensation, which corresponds to the relative offset value.

Similarly, when multiple human face areas are recognized in step S22, an average of the multiple relative offset values can be determined for obtaining the volume compensation.

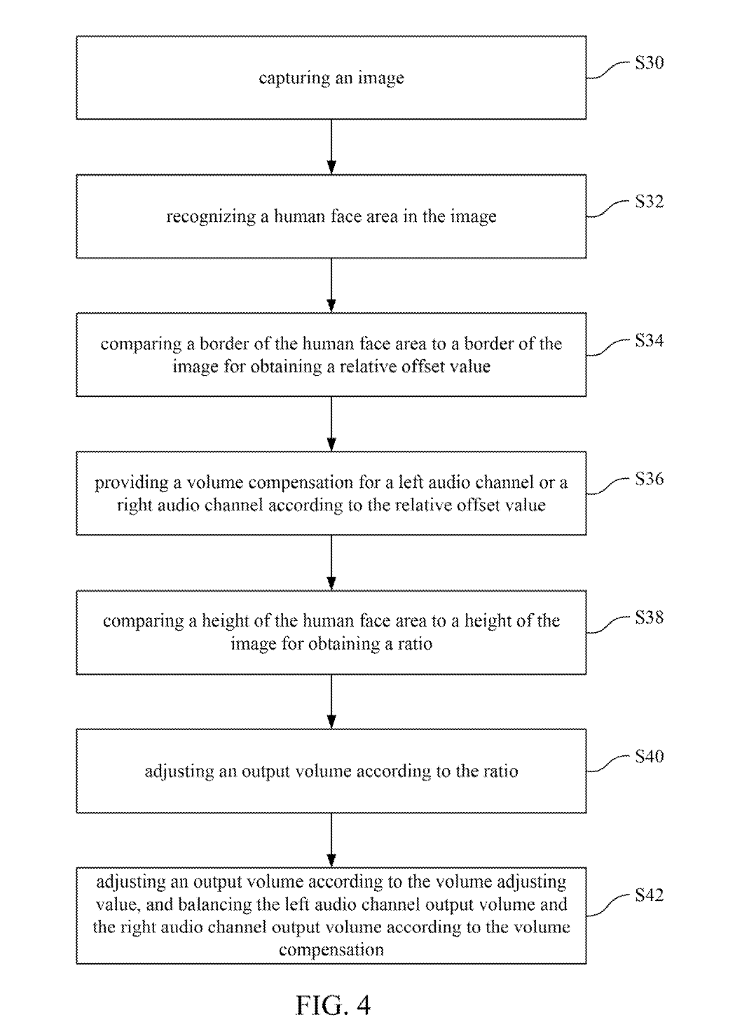

FIG. 4 is a flow chart of a fourth embodiment of the method for auto-adjusting audio output volume of the invention. In this embodiment, the output volume and the balance of the left and right audio channels are adjusted according to the distance and the angle between the user and the electronic apparatus. In step S30, an image is captured.

In step S32, a human face area is recognized in the image.

In step S34, a border of the human face area is compared to a border of the image for obtaining a relative offset value.

In step S36, a volume compensation for a left audio channel or a right audio channel is provided according to the relative offset value.

In step S38, a height of the human face area is compared to a height of to the image for obtaining a ratio.

In step S40, a volume adjusting value is provided according to the ratio.

In step S42, an output volume is adjusted according to the volume adjusting value, and the left audio channel output volume and the right audio channel output volume are balanced according to the volume compensation.

Details for steps S30 to S42 are described in previous embodiments.

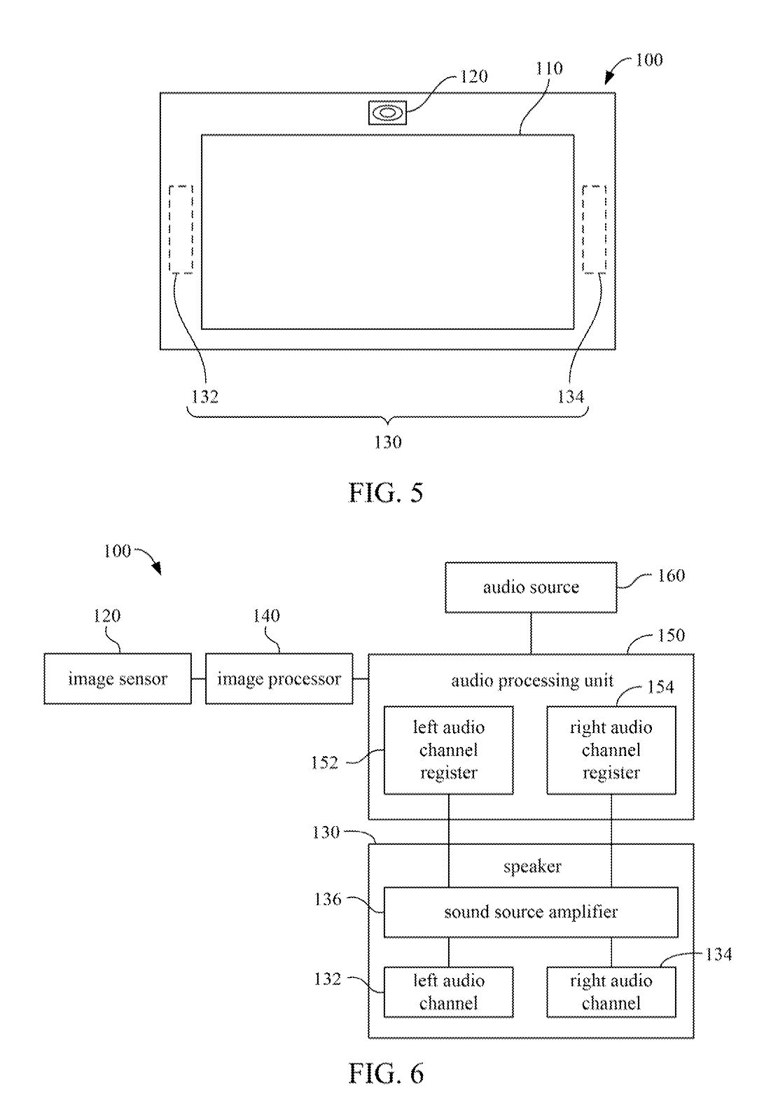

FIG. 5 is a schematic diagram of an embodiment of an electronic apparatus for auto-adjusting audio output volume of the invention. The electronic apparatus 100 includes a screen 110, an image sensor 120, and a speaker 130. The image sensor 120 is disposed near the screen 110 for capturing an image in front of the screen 110. The speaker 130 includes a left audio channel 132 and a right audio channel 134. The left audio channel 132 and the right audio channel 134 each has at least one amplifier. The left audio channel 132 and the right audio channel 134 can be embedded in or external to the electronic apparatus 100.

FIG. 6 is a block diagram of the electronic apparatus 100 shown in FIG. 5. The electronic apparatus 100 includes the image sensor 120, the speaker 130, an image processor 140, an audio processing unit 150, and an audio source 160.

The image sensor 120 is utilized for capturing an image. The image sensor 120 can be a charge-coupled device (CCD) image sensor or a complementary metal-oxide-semiconductor (CMOS) image sensor.

The image captured by the image sensor 120 is sent to the image processor 140. The image processor 140 can recognize a human face area in the image with a facial recognition technique. The image processor 140 may further compare a height of the human face area to the image for obtaining a ratio to obtain a volume adjusting value to adjust the output volume. The image processor 140 may further compare a border of the human face area to a border of the image for obtaining a relative offset value to obtain a volume compensation to adjust left audio channel output volume and/or right audio channel output volume.

The audio processing unit 150 receives an audio source data from the audio source 160 and receives the volume adjusting value and/or the volume compensation from the image processor 140. The audio processing unit 150 includes a left audio channel register 152 and a right audio channel register 154. The volume adjusting value and/or the volume compensation can be sent to the let audio channel register 152 and the right audio channel register 154 to correct data stored therein. The audio processing unit 150 transforms the digital audio source data to an analog sound data. The output volume of the sound data is adjusted according to the volume adjusting value and/or the volume compensation.

The audio processing unit 150 is connected to the speaker 130. The speaker 130 includes the left audio channel 132, the right audio channel 134, and a sound source amplifier 136. The sound data provided by the audio processing unit 150 is sent to the left audio channel 132 and the right audio channel 134 via the sound source amplifier 136. The output volume of the left audio channel 132 is controlled by the left audio channel register 152. The output volume of the right audio channel 134 is controlled by the right audio channel register 154.

According to above embodiments, the present disclosure can automatically adjust the output volume and/or balance the left and right audio channel by detecting the distance and/or the angle between the user and the screen to provide a better display quality.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for auto-adjusting audio output volume, comprising:
capturing an image;
recognizing a human face area in the image;
comparing a height of the human face area to a height of the image for obtaining a ratio; and
adjusting an output volume according to the ratio.

2. A method for auto-adjusting audio output volume, comprising:
capturing an image;
recognizing a human face area of the image;
comparing a border of the human face area to a border of the image for obtaining a relative offset value; and
adjusting a right audio channel output volume or a left audio channel output volume according to the relative offset value.

3. The method for auto-adjusting audio output volume of claim 2, wherein the step of comparing the border of the human face area to the border of the image comprises:
comparing a left border of the human face area and a left border of the image for obtaining the relative offset value for adjusting the left audio channel output volume.

4. The method for auto-adjusting audio output volume of claim 2, wherein the step of comparing the border of the human face area to the border of the image comprises:
comparing a right border of the human face area and a right border of the image for obtaining the relative offset value for adjusting the right audio channel output volume.

5. The method for auto-adjusting audio output volume of claim 2, wherein a volume compensation of the left audio channel or the right audio channel is obtained from the equation:
(O/W)*M,
where O is the relative offset value, W is a width of the image, and M is a maximum compensation.

6. The method for auto-adjusting audio output volume of claim 2, further comprising:
comparing a height of the human face area to a height of the image for obtaining a ratio; and
adjusting the left audio channel output volume and the right audio channel output volume according to the ratio.

7. An electronic apparatus for auto-adjusting audio output volume, comprising:
an image sensor for capturing an image;
an image processor for recognizing a human face area in the image and comparing a height of the human face area to a height of the image for obtaining a volume adjusting value;
an audio processing unit for receiving the volume adjusting value and an audio source data, the audio processing unit further transforming the audio source data to a sound data, wherein an output volume of the sound data is adjusted according to the volume adjusting value; and
a speaker for outputting the sound data provided by the audio processing unit.

8. An electronic apparatus for auto-adjusting audio output volume, comprising:
an image sensor for capturing an image;
an image processor for recognizing a human face area in the image and comparing a border of the human face area to a border of the image for obtaining a volume compensation value;
an audio processing unit for receiving the volume compensation value and an audio source data, the audio processing unit further transforming the audio source data to a sound data, wherein the audio processing unit comprises a left audio channel register and a right audio channel register, and the volume compensation value is sent to the left audio channel register or the right audio channel register; and
a speaker for outputting the sound data provided by the audio processing unit, wherein the speaker comprises a left audio channel and a right audio channel, an output volume of the left audio channel is controlled by the left audio channel register, and an output volume of the right audio channel is controlled by the right audio channel register.
